(19) United States
(12) Patent Application Publication
(10) Pub. No.: US 2025/0389777 A1
(43) Pub. Date: Dec. 25, 2025

(54) ESTIMATION DEVICE, ENERGY STORAGE APPARATUS, ESTIMATION METHOD, AND COMPUTER PROGRAM

(71) Applicant: GS Yuasa International Ltd., Kyoto-shi, Kyoto (JP)

(72) Inventor: Yusuke YOSHIOKA, Kyoto-shi, Kyoto (JP)

(21) Appl. No.: 18/879,502

(22) PCT Filed: Jun. 21, 2023
(86) PCT No.: PCT/JP2023/022950

§ 371 Date: Dec. 27, 2024

(30) Foreign Application Priority Data
Jun. 30, 2022 (JP) 2022-106216

(51) Int. Cl. G01R 31/367; G01R 31/387; G01R 31/392; H01M 10/48

(52) U.S. Cl. CPC G01R 31/367; G01R 31/387; G01R 31/392; H01M 10/48

(57) ABSTRACT

An estimation device includes a control unit that estimates full charge capacity or degree of deterioration of an energy storage device. The control unit causes the energy storage device to be discharged at constant voltage until a necessary SOC is reached, causes the energy storage device to be charged to its full charge state, and estimates full charge capacity or degree of deterioration of the energy storage device based on an integrated value of charge current from the necessary electric SOC to the full charge state or an integrated value of discharge current from the full charge state to the necessary SOC.

### CROSS REFERENCE TO RELATED APPLICATIONS

This application is a National Stage Application, filed under 35 U.S.C. § 371, of International Application No. PCT/JP2023/022950, filed Jun. 21, 2023, which international application claims priority to and the benefit of Japanese Application No. 2022-106216, filed Jun. 30, 2022; the contents of both of which are hereby incorporated by reference in their entirety.

### BACKGROUND

### Technical Field

The present application generally relates to an estimation device, an energy storage apparatus, an estimation method, and a computer program.

### Description of Related Art

In recent years, electrification of devices such as a brake and power steering in a mobile object is advancing in order to realize autonomous driving. More advanced stability is required for power supply from an energy storage apparatus such as a 12 volt (V) battery to such an electric device (also referred to as accessories). In view of the above, there is an increasing need to monitor and estimate power supply capability in a 12 V battery, what is called a state of function (SOF).

A battery deteriorates with conduction (charge and/or discharge) and passage of time, and its full charge capacity decreases. In order for stable power supply from a battery to accessories it is necessary to grasp full charge capacity that decreases as described above.

JP-A-2004-236381 discloses a technique of determining deterioration of a battery by setting a state of charge (SOC) of the battery to a predetermined SOC with high accuracy.

### BRIEF SUMMARY

There is a method of discharging a battery to a low SOC (for example, near zero % of SOC), then charging the battery to a full charge state, and estimating a full charge capacity of the battery from an integrated value of charge current from the low SOC to the full charge state. Consideration for applying this method to an energy storage cell and an energy storage apparatus including a plurality of energy storage cells for applications in which a mobile object is required to exhibit predetermined power supply capability even when the mobile object is activated at any time, such as a battery for a mobile object, has not been sufficiently made. Hereinafter, an energy storage cell and an energy storage apparatus are collectively referred to as “energy storage device”.

One aspect of the present invention provides an estimation device capable of estimating full charge capacity or degree of deterioration of an energy storage device while securing power supply capability, an energy storage apparatus, an estimation method, and a computer program.

An estimation device according to one aspect of the present invention includes a control unit that estimates full charge capacity or degree of deterioration of an energy storage device. The control unit estimates full charge capacity or degree of deterioration of the energy storage device based on an integrated value of charge current from a necessary SOC to a full charge state of the energy storage device, in a case where the energy storage device is discharged at constant voltage (subjected to CV discharge) until the necessary SOC is reached and the energy storage device is charged to the full charge state, or an integrated value of discharge current from the full charge state to the necessary SOC.

According to the above aspect, it is possible to estimate full charge capacity or degree of deterioration of an energy storage device while securing power supply capability (necessary SOC).

### BRIEF DESCRIPTION OF THE FIGURES

FIG. 1 is a perspective view illustrating a configuration example of an energy storage apparatus on which an estimation device according to an embodiment is mounted.

FIG. 2 is an exploded perspective view illustrating a configuration example of the energy storage apparatus.

FIG. 3 is a block diagram illustrating a configuration example of the energy storage apparatus.

FIG. 4 is a diagram for explaining an estimation method for power supply capability of the energy storage apparatus.

FIG. 5 is a circuit diagram illustrating an example of an energy storage apparatus model.

FIG. 6 is a diagram illustrating a part of an SOC-open circuit voltage (OCV) profile.

FIG. 7 is a diagram illustrating a method of determining a necessary SOC.

FIG. 8 is a diagram for explaining voltage behavior of an energy storage cell in a case where CV discharge is performed.

FIG. 9 is a diagram for explaining voltage behavior of the energy storage cell in a case where constant current discharge (CC discharge) is performed.

FIG. 10 is a diagram for explaining voltage behavior of the energy storage cell in a case where charging from a necessary SOC to a full charge state.

### DETAILED DESCRIPTION OF VARIOUS EMBODIMENTS

Hereinafter, an outline of an embodiment will be described.
(1) An estimation device includes a control unit that estimates full charge capacity or degree of deterioration of an energy storage device. The control unit estimates full charge capacity or degree of deterioration of the energy storage device based on an integrated value of charge current from a necessary SOC to a full charge state of the energy storage device, in a case where the energy storage device is discharged at constant voltage (subjected to CV discharge) until the necessary SOC is reached and the energy storage device is charged to the full charge state, or an integrated value of discharge current from the full charge state to the necessary SOC.

Here, the “necessary SOC” means an SOC in the vicinity of an end-of-discharge point which is determined such that the energy storage device can supply predetermined electric power to an electric load connected to the energy storage device. In the energy storage device mounted on a mobile object, the necessary SOC may be an SOC in which a stopped mobile object can supply predetermined electric power to start operation.

The “degree of deterioration” may be a capacity retention ratio of an energy storage device or a health condition (SOH).

The CV discharge may be ended at a time point at which discharge current becomes equal to or less than a threshold (for example, one ampere or less). An energy storage device may be subjected to CV discharge in the entire region in a process of discharge for estimating full charge capacity or degree of deterioration, or may be subjected to CV discharge in the vicinity of an end-of-discharge point after being subjected to CC discharge (that is, may be subjected to CCCV discharge).

According to the above estimation device, it is possible to accurately estimate full charge capacity or degree of deterioration of an energy storage device based on the necessary SOC reached by using CV discharge.

In CC discharge in which discharge is stopped based on detected voltage of an energy storage device, degree of difficulty of reaching a target SOC is high due to influence of a polarization characteristic that changes according to an operation status (temperature, current, degree of deterioration of the energy storage device, and the like) of the energy storage device. For this reason, if full charge capacity or degree of deterioration of an energy storage device is estimated based on the necessary SOC reached using CC discharge, estimation accuracy is not stabilized.

On the other hand, the estimation device uses the necessary SOC that is accurately reached by CV discharge of an energy storage device in order to estimate full charge capacity or degree of deterioration, and for this reason, estimation accuracy is stabilized.
(2) In the estimation device according to (1) above, the necessary SOC may be determined to be included in a non-plateau region in an SOC-open circuit voltage (OCV) profile of the energy storage device.

In a lithium ion battery (what is called an LFP battery) containing lithium iron phosphate (LiFePO₄) as a positive active material, a “plateau region” in which a voltage change accompanying charging and discharging hardly occurs is included in the SOC-OCV profile. The “non-plateau region” means an SOC region in the vicinity of an end-of-discharge point where the SOC-OCV profile has a slope equal to or more than a predetermined value (slope to an extent that OCV reset can be performed). An energy storage device other than an LFP battery also includes an SOC region where a slope of the SOC-OCV profile is large in the vicinity of an end-of-discharge point. The SOC region having a large slope is referred to as a “non-plateau region”.

According to the above configuration, an energy storage device is discharged to the necessary SOC, an SOC value (that is, an OCV-reset SOC value) closer to a true value is acquired from voltage of the energy storage device detected after depolarization, and an integrated value of charge current is added to the SOC value, so that full charge capacity or degree of deterioration of the energy storage device can accurately be estimated.
(3) In the estimation device according to (1) or (2) above, the necessary SOC may be determined using an energy storage device model that simulates voltage behavior of the energy storage device accompanying discharge.

The energy storage device model may be an equivalent circuit model, but is not limited to this. The equivalent circuit model may simulate voltage behavior of a single energy storage cell or may simulate voltage behavior of an energy storage apparatus including a plurality of energy storage cells.

Alternatively, the energy storage device model may be a lookup table in which internal resistance, temperature, and the necessary SOC are stored in association with each other.

According to the above configuration, the necessary SOC in consideration of influence of a polarization characteristic changing according to an operation status (temperature, degree of deterioration of an energy storage device, and the like) of the energy storage device is derived from the energy storage device model.
(4) In the estimation device according to (3) above, the energy storage device model may be an energy storage apparatus model that simulates behavior of an energy storage apparatus including a plurality of energy storage cells and a conductive member.

Here, the “conductive member” means a member structuring a conductive path (power line) in the energy storage apparatus other than the energy storage device. The conductive member may include a wiring member (for example, a wiring, a bus bars, and the like), a connection portion (for example, a welded portion or a connecting portion using a screw or the like) of the wiring member, and a circuit breaker (for example, a semiconductor switch).

According to the above configuration, by using the energy storage apparatus model, the necessary SOC can be accurately determined, and full charge capacity or degree of deterioration of an energy storage device can be accurately estimated.
(5) In the estimation device according to (4) above, a resistance component of the conductive member may be given to the energy storage apparatus model.

The resistance component of the conductive member may be obtained by adding up resistance values of individual conductive members, or one or a plurality of resistance values may be experimentally obtained from a test circuit. A plurality of the resistance components of the conductive member may be prepared according to temperature.

According to the above configuration, the necessary SOC can be accurately determined in consideration of a resistance component (hereinafter, also referred to as structural resistance) of the conductive member, and full charge capacity or degree of deterioration of an energy storage device can be accurately estimated. For example, as in a low-voltage battery (12 V battery, 48 V battery, or the like), in a case where the total number of energy storage cells is relatively small, internal resistance (for example, 10 mΩ) and structural resistance (for example, 2 mΩ) of the energy storage cells are of the same order, and the structural resistance cannot be ignored, appropriate estimation can be performed.
(6) In the estimation device according to any of (1) to (5) above, the control unit may start a search for the necessary SOC in a predetermined order from any of a plurality of SOC values included in the non-plateau region.

Here, the “predetermined order” may be order in a direction in which an SOC value increases or a direction in which an SOC value decreases from a low SOC value or a high SOC value included in the non-plateau region, but is not limited to this. The “low SOC value” may be a lowest SOC value in the non-plateau region, and the “high SOC value” may be a highest SOC value in the non-plateau region, but the values are not limited to those. The “low SOC value” is set to an SOC value lower than the “high SOC value”.

The control unit may be configured to be able to select from which of the low SOC value and the high SOC value included in the non-plateau region a search for the necessary SOC is started.

According to the above configuration, it is possible to select whether to give priority to accuracy of estimation of full charge capacity or degree of deterioration of an energy storage device or to give priority to the estimation in short time. In accordance with an instruction from a host device or in accordance with an operation status of an energy storage device, from which one of the low SOC value and the high SOC value the necessary SOC is to be searched for may also be determined.
(7) An energy storage apparatus includes the estimation device according to any of (1) to (6) above, and a plurality of energy storage cells.
(8) An estimation method of estimating full charge capacity or degree of deterioration of an energy storage device includes causing the energy storage device to be discharged at constant voltage until the necessary SOC is reached, causing the energy storage device to be charged to a full charge state of the energy storage device, and estimating the full charge capacity or the degree of deterioration of the energy storage device based on an integrated value of charge current from the necessary SOC to the full charge state or an integrated value of discharge current from the full charge state to the necessary SOC.
(9) A computer program causes a computer that estimates full charge capacity or degree of deterioration of an energy storage device to execute processing of estimating the full charge capacity or the degree of deterioration of the energy storage device based on an integrated value of charge current from a necessary state of charge (SOC) to a full charge state, in a case where the energy storage device is discharged at constant voltage until the necessary SOC is reached and the energy storage device is charged to the full charge state, or an integrated value of discharge current from the full charge state to the necessary SOC.

Hereinafter, specific description will be made with reference to the drawings illustrating the embodiment.

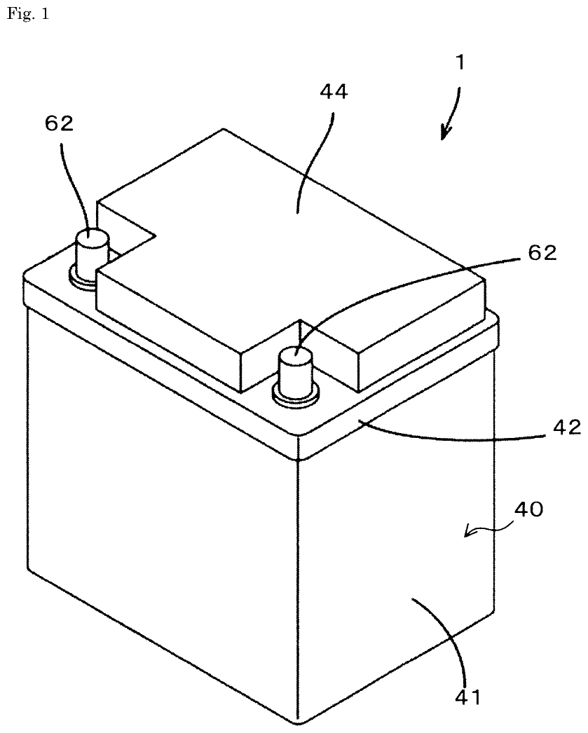

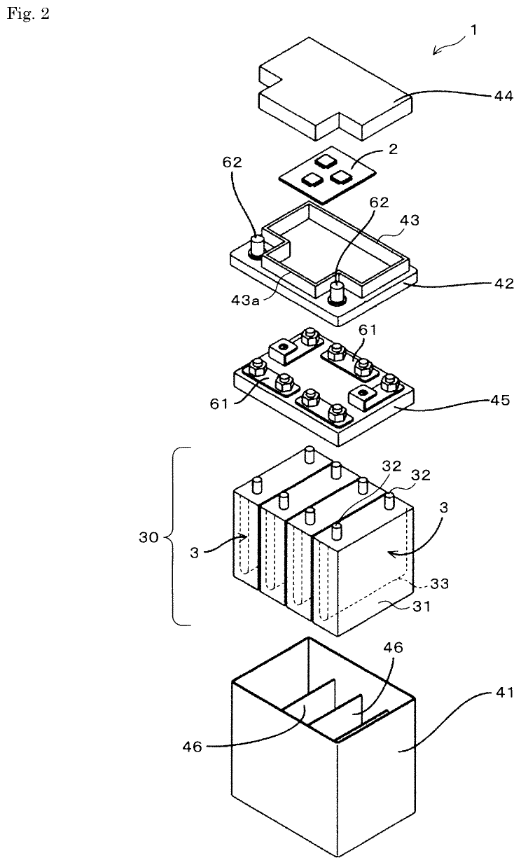

FIG. 1 is a perspective view illustrating a configuration example of an energy storage apparatus 1 on which an estimation device according to the embodiment is mounted, and FIG. 2 is an exploded perspective view illustrating a configuration example of the energy storage apparatus 1. The energy storage apparatus 1 is a 12 V battery (low voltage battery) suitably mounted on, for example, an engine vehicle, an electric vehicle (EV), a hybrid electric vehicle (HEV), or a plug-in hybrid electric vehicle (PHEV). The energy storage apparatus 1 may be mounted on another mobile object such as a flying object, a railway train, or a ship.

The energy storage apparatus 1 includes an estimation device 2, a plurality of energy storage cells 3, and a rectangular parallelepiped housing case 40 which houses the estimation device 2 and a plurality of the energy storage cells 3. The energy storage cell 3 may be a battery cell such as a lithium ion secondary battery or an electrochemical cell such as a capacitor. The estimation device 2 is, for example, a battery management system (BMS).

Four of the energy storage cells 3 are connected in series to form an assembled battery 30. Alternatively, some of the energy storage cells 3 may be connected in parallel. For example, the assembled battery 30 may include twelve of the energy storage cells 3 connected in three parallel and four series.

The housing case 40 is made from synthetic resin. The housing case 40 includes a case body 41, a lid portion 42 that closes an opening portion of the case body 41, a housing portion 43 provided on the lid portion 42, a cover 44 that covers the housing portion 43, an inner lid (bus bar frame) 45, and a partition plate 46. The inner lid 45 and the partition plate 46 do not need to be provided. The energy storage cell 3 is inserted between the partition plates 46 of the case body 41.

A plurality of bus bars 61 made from metal are placed on the inner lid 45. The inner lid 45 is arranged in the vicinity of a terminal surface where a cell terminal 32 of the energy storage cell 3 is provided, adjacent ones of the cell terminals 32 of adjacent ones of the energy storage cells 3 are connected by the bus bar 61, so that the energy storage cells 3 are connected in series. The bus bar 61 is an example of a conductive member.

The housing portion 43 includes a box shape, and includes a protruding portion 43a protruding outward at a central portion of one long side in plan view. A pair of external terminals 62 and 62 made from metal such as a lead alloy and having different polarities are provided on both sides of the protruding portion 43a on the lid portion 42. The estimation device 2 is housed in the housing portion 43. The estimation device 2 is connected to the energy storage cell 3 via a wiring member (not illustrated) and the bus bar 61. The estimation device 2 may be arranged, for example, adjacent to an upper side or a side of the assembled battery 30 instead of being housed in the housing portion 43.

The energy storage cell 3 includes a case 31 having a hollow rectangular parallelepiped shape, and a pair of the cell terminals 32 and 32 having different polarities and provided on one side surface (terminal surface, upper surface) of the case 31. The case 31 houses an electrode assembly 33 formed by stacking a positive electrode, a separator, and a negative electrode, and an electrolyte (electrolyte solution) (not illustrated).

Although details are not illustrated, the electrode assembly 33 is configured by placing a sheet-like positive electrode and negative electrode on each other with two sheet-like separators interposed between them and winding (longitudinally winding or laterally winding) them. The separator is formed of a porous resin film. As the porous resin film, a porous resin film made from resin such as polyethylene (PE) or polypropylene (PP) can be used.

The positive electrode is an electrode plate in which a positive active material layer is formed on a surface of an elongated strip-shaped positive electrode substrate made from, for example, aluminum, an aluminum alloy, or the like. The positive active material layer contains a positive active material. As the positive active material used for the positive active material layer, a material capable of occluding and releasing a lithium ion can be used. As the positive active material, for example, LiFePO₄ is used, but the positive active material is not limited to this, and what is called a ternary positive active material may be used. The positive active material layer may further contain a conductive assistant, a binder, and the like.

The negative electrode is an electrode plate in which a negative active material layer is formed on a surface of an elongated strip-shaped negative electrode substrate made from, for example, copper, a copper alloy, or the like. The negative active material layer contains a negative active material. As the negative active material, a material capable of occluding and releasing a lithium ion can be used. Examples of the negative active material include graphite, hard carbon, and soft carbon. The negative active material layer may further contain a binder, a thickener, and the like.

As an electrolyte housed in the housing case 40 together with the electrode assembly 33, the same electrolyte as that of a conventional lithium ion secondary battery can be used. For example, an electrolyte in which a supporting electrolyte is contained in an organic solvent can be used as the electrolyte. As the organic solvent, for example, an aprotic solvent such as carbonates, esters, and ethers is used. As the supporting electrolyte, for example, lithium salt such as LiPF₆, LiBF₄, or LiClO₄ is suitably used. The electrolyte may contain, for example, various additives such as a gas generating agent, a film forming agent, a dispersant, and a thickener.

FIG. 2 illustrates, as an example of the energy storage cell 3, a prismatic lithium ion battery including the electrode assembly 33 of a winding type. Alternatively, the energy storage cell 3 may be a cylindrical lithium ion battery or a laminate type (pouch type) lithium ion battery. The energy storage cell 3 may be a lithium ion battery including a stacked type electrode assembly. The energy storage cell 3 may be an all-solid-state lithium ion battery using a solid electrolyte.

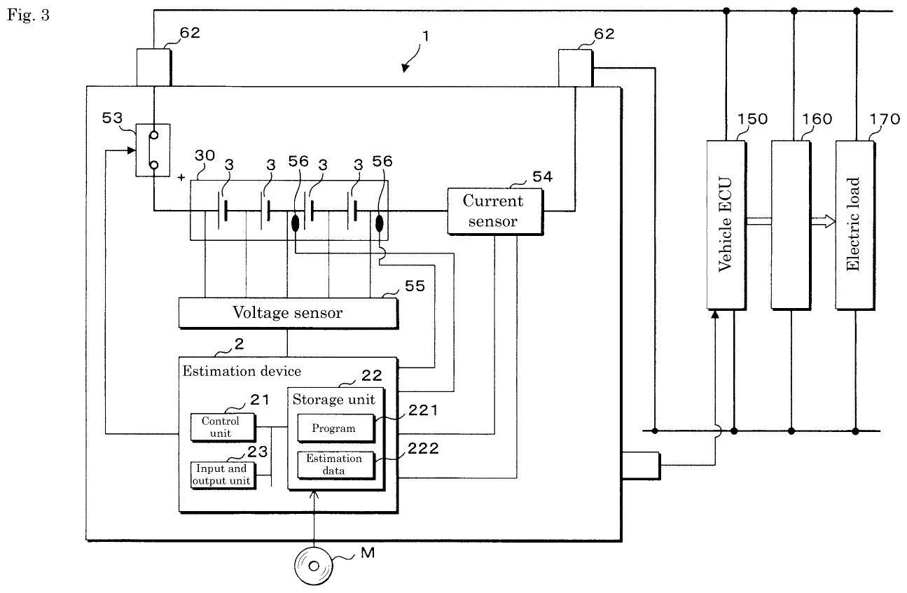

FIG. 3 is a block diagram illustrating a configuration example of the energy storage apparatus 1. The energy storage apparatus 1 includes the estimation device 2, the assembled battery 30, a circuit breaker 53, a current sensor 54, a voltage sensor 55, and a temperature sensor 56.

A vehicle electronic control unit (ECU) 150, a DC-DC converter 160 that converts electric power from a high-voltage battery, and an in-vehicle electric load 170 (accessories) are electrically connected to the energy storage apparatus 1 via the external terminals 62 and 62. In an engine vehicle, instead of the converter 160, an alternator that is a generator that generates power by power of an engine is used.

The vehicle ECU 150 is a vehicle control unit, and controls the converter 160 and the electric load 170. The vehicle ECU 150 controls charge voltage and an allowable charge-discharge amount of the energy storage apparatus 1 by controlling the converter 160 and the electric load 170 based on an estimation result regarding charge-discharge performance (power supply capability) received from the estimation device 2. The vehicle ECU 150 is an example of a “host device”.

The estimation device 2 is a flat-plate-shaped circuit board that estimates a state of each of the energy storage cells 3 at a predetermined timing and estimates charge-discharge performance of the energy storage apparatus 1. A shape of the estimation device 2 is not limited to a flat plate shape. The estimation device 2 may be configured as a circuit board unit in which the circuit breaker 53, the current sensor 54, the voltage sensor 55, and the like are mounted on a circuit board. The estimation device 2 includes a control unit 21, a storage unit 22, an input and output unit 23, and the like.

The control unit 21 is an arithmetic circuit including a central processing unit (CPU), a read only memory (ROM), a random access memory (RAM), and the like. The CPU included in the control unit 21 executes various computer programs stored in the ROM or the storage unit 22 and controls operation of each unit of the hardware described above, so as to cause the entire apparatus to function as an estimation device. The control unit 21 may have a function of a timer that measures elapsed time from when a measurement start instruction is given to when a measurement end instruction is given, a counter that counts the number, a clock that outputs date and time information, and the like.

The storage unit 22 is a non-volatile storage device such as a flash memory. The storage unit 22 stores a program and data referred to by the control unit 21. The computer program stored in the storage unit 22 includes a program 221 for estimating information on whether or not the energy storage apparatus 1 can be charged or discharged. Data stored in the storage unit 22 includes estimation data 222 used for the program 221 and an energy storage apparatus model of the energy storage apparatus 1 used in a simulation. The energy storage apparatus model is described by configuration information indicating a circuit configuration, a value of each element structuring the energy storage apparatus model, and the like. The storage unit 22 stores configuration information indicating a circuit configuration of such an energy storage apparatus model, a value of each element structuring the energy storage apparatus model, and the like.

A computer program (computer program product) stored in the storage unit 22 may be provided by a non-transitory recording medium M in which the computer program is recorded in a readable manner. The recording medium M is a portable memory such as a CD-ROM, a USB memory, or a secure digital (SD) card. The control unit 21 reads a desired computer program from the recording medium M by using a reading device (not illustrated), and stores the read computer program in the storage unit 22. Alternatively, the computer program may be provided by communication. The program 221 can be loaded to be executed on a single computer or on a plurality of computers arranged on one site or distributed over a plurality of sites and interconnected by a communication network.

The input and output unit 23 includes an input and output interface for connecting an external device. The vehicle ECU 150, the circuit breaker 53, the current sensor 54, the voltage sensor 55, the temperature sensor 56, and the like are connected to the input and output unit 23.

The circuit breaker 53 includes, for example, a semiconductor switch such as an FET, a relay including a mechanical contact, or the like. The circuit breaker 53 cuts off current of the assembled battery 30 by switching between an on state and an off state according to a control signal output from the control unit 21.

The current sensor 54 is connected in series to the assembled battery 30. The current sensor 54 may be a shunt resistor. The current sensor 54 measures current flowing through the energy storage cell 3 in time series based on voltage between terminals of a resistance element. Discharge and charge can be determined from polarity (positive or negative) of the voltage between terminals. Alternatively, the current sensor 54 may be a magnetic sensor. The control unit 21 acquires current data measured by the current sensor 54 as needed through the input and output unit 23.

The voltage sensor 55 is connected in parallel to each of the energy storage cells 3. The voltage sensor 55 is connected to both ends of each of the energy storage cells 3, and measures terminal voltage of each of the energy storage cells 3 in time series. The control unit 21 acquires, as needed, data of voltage of each of the energy storage cells 3 and total voltage of the assembled battery 30 measured by the voltage sensor 55 through the input and output unit 23.

The temperature sensor 56 is provided in the vicinity of the energy storage cell 3 and detects temperature related to the energy storage apparatus 1. The temperature sensor 56 may be a thermocouple, a thermistor, or the like. Temperature regarding the energy storage apparatus 1 may be temperature around the energy storage cell 3 or the energy storage apparatus 1, or the like. The control unit 21 acquires temperature data measured by the temperature sensor 56 as needed through the input and output unit 23.

In a case where an estimation result as to whether conduction is possible or not in the energy storage apparatus 1 is obtained, the control unit 21 outputs information based on the estimation result from the input and output unit 23 to a vehicle ECU. The vehicle ECU executes various pieces of processing based on the information acquired from the estimation device 2.

The input and output unit 23 may include an interface for connecting a display device. An example of the display device is a liquid crystal display device. In a case where an estimation result as to whether conduction is possible or not in the energy storage apparatus 1 is obtained, the control unit 21 outputs information based on the estimation result from the input and output unit 23 to the display device. The display device displays an estimation result based on the information output from the input and output unit 23.

The input and output unit 23 may include a communication interface for communication with an external device. An external device communicatively connected to the input and output unit 23 is a terminal device such as a personal computer or a smartphone used by the user, an administrator, or the like. In a case where an estimation result as to whether conduction is possible or not in the energy storage apparatus 1 is obtained, the control unit 21 transmits information based on the estimation result from the input and output unit 23 to a terminal device. The terminal device receives the information transmitted from the input and output unit 23, and displays an estimation result on a display of the terminal device based on the received information. The estimation device 2 may include a notification unit such as an LED lamp or a buzzer in order to notify the user of an estimation result as to whether or not conduction is possible in the energy storage apparatus 1.

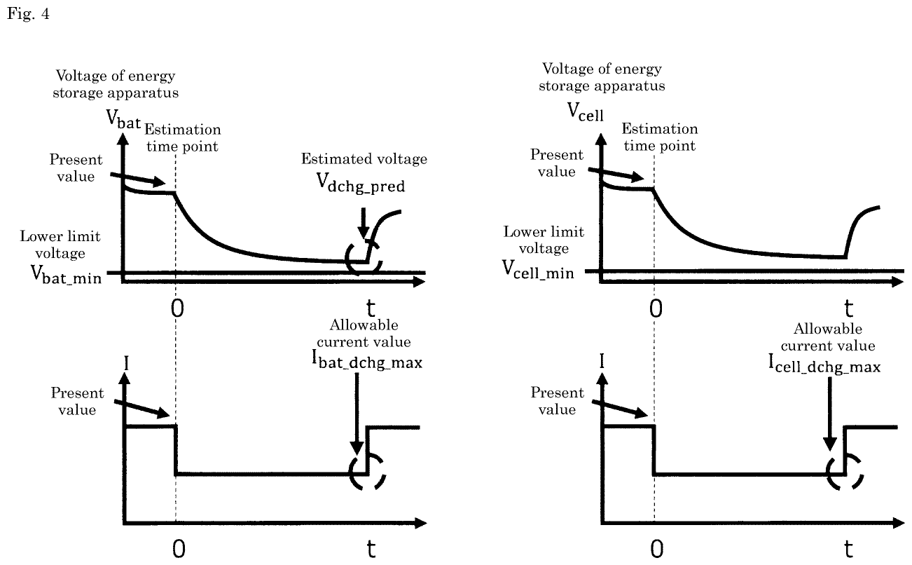

FIG. 4 is a diagram for explaining an estimation method for discharge performance (power supply capability) in a case where a conduction pattern preannounced from the vehicle ECU 150 (host device) is discharge. In FIG. 4, an upper left graph shows a temporal change in a voltage value of the energy storage apparatus 1 due to conduction, and a lower left graph shows a temporal change in a current value of the energy storage apparatus 1 due to conduction. In FIG. 4, an upper right graph shows a temporal change in a voltage value of the energy storage cell 3 due to conduction, and a lower right graph shows a temporal change in a current value of the energy storage cell 3 due to conduction.

A case where conduction is performed for a predetermined discharge current value for the energy storage apparatus 1 over predetermined time (t seconds) with reference to an estimation time point is assumed. As illustrated in FIG. 4, when a discharge current value is constant, a voltage value of the energy storage apparatus 1 decreases along with discharge. Similarly, a voltage value of each of the energy storage cells 3 decreases along with discharge. In a case where estimated voltage after t seconds is larger than preset lower limit voltage of the energy storage apparatus 1, it can be determined that conduction is possible. In a case where estimated voltage after t seconds is smaller than preset lower limit voltage of the energy storage apparatus 1, it can be determined that conduction is not possible.

Similarly, whether or not conduction is possible in a case where conduction is performed for a predetermined charge current value for the energy storage apparatus 1 over predetermined time with reference to an estimation time point can be determined. In a case where estimated voltage after t seconds is larger than upper limit voltage of the energy storage apparatus 1, it can be determined that conduction is not possible.

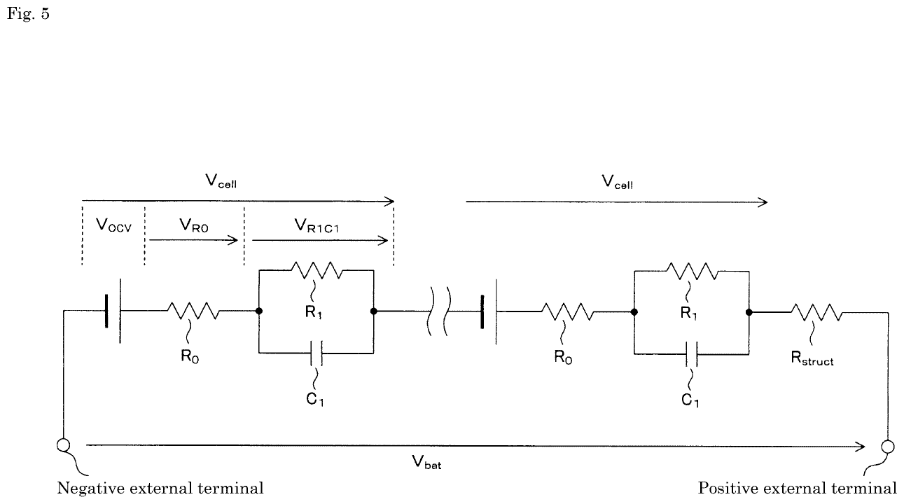

FIG. 5 is a circuit diagram illustrating an example of an energy storage apparatus model that simulates behavior of the energy storage apparatus 1. The energy storage apparatus model illustrated in FIG. 5 is an equivalent circuit model, and simulates charge-discharge behavior of the energy storage apparatus 1 by combining a voltage source of the energy storage apparatus 1 including a plurality of the energy storage cells 3 and circuit elements such as a resistor and a capacitor.

The equivalent circuit model illustrated in FIG. 5 includes n of the energy storage cells 3 connected in series between a positive external terminal and a negative external terminal, and a structural resistor. Each of the energy storage cells 3 includes a constant voltage source, a DC resistor that simulates a DC resistance component, and an RC parallel circuit for simulating a transient polarization characteristic.

The structural resistor simulates a resistance component (structural resistance) of a conductive member in the energy storage apparatus 1, and includes a resistance element R_{struct}. The resistance element R_{struct} represents a resistance component in each of a plurality of members including, for example, the bus bar 61 and the circuit breaker 53. The resistance element R_{struct} may be given as a value that varies in accordance with temperature.

In each of the energy storage cells 3, a constant voltage source is a voltage source (electromotive force) that outputs DC voltage. Voltage output from the constant voltage source is OCV of the energy storage cell 3 and is referred to as V_{OCV}. V_{OCV} is given as a value that varies corresponding to an SOC of the energy storage cell 3, and is given, for example, as a function of an SOC.

In each of the energy storage cells 3, a DC resistor simulates a DC resistance component (DC impedance) of the energy storage apparatus 1, and includes a resistance element R₀. The resistance element R₀ is given as a value that varies corresponding to conduction current, voltage, an SOC, temperature, and the like. When impedance of the DC resistor is determined, voltage generated in the DC resistor when current I flows through the equivalent circuit model can be calculated. Voltage generated in the DC resistor is referred to as DC resistance voltage R₀I.

In each of the energy storage cells 3, an RC parallel circuit includes a resistance element R₁ and a capacitance element C₁ connected in parallel. The resistance element R₁ and the capacitance element C₁ are given as values that vary corresponding to an SOC, temperature, and the like. Impedance of an RC parallel circuit is determined by the resistance element R₁ and the capacitance element C₁. When impedance of an RC parallel circuit is determined, voltage generated in the RC parallel circuit when the current I flows through this equivalent circuit model can be calculated. Voltage generated in an RC parallel circuit is referred to as polarization voltage V_{RIC1}.

The resistance elements R_{struct}, R₀, and R₁ and the capacitance element C₁ (hereinafter, also referred to as a circuit parameter) are obtained by a publicly-known method. The circuit parameter can be set, for example, in consideration of a relationship between temperature, an SOC, and the like based on actual measurement data of a battery test. The estimation device 2 stores an obtained circuit parameter, temperature, an SOC, and the like in association with each other as the estimation data 222. The circuit parameter may be identified using an inspection result at the time of product shipment or a measurement value of a sensor after mounting on a product, or may be appropriately corrected (calibrated) based on a use history after mounting on a product.

From the voltage summation rule, the polarization voltage V_{RIC1} of each of the energy storage cells 3 in a case where an estimation time point is t=0 can be estimated by Formula (1) below using cell voltage V_{cell} of the energy storage cell 3, V_{OCV}, I, and R₀ of the energy storage cell 3 generated at the time of discharge.

$$[ Mathematical formula 1 ]$$

$${V}_{R 1 C 1} ( 0 ) = {V}_{cell} ( 0 ) - {V}_{ocv} ( 0 ) - {R}_{0} I ( 0 ) \qquad ( 1 )$$

As the cell voltage V_{cell} and I, a measurement value of the current sensor 54 and the voltage sensor 55 (see FIG. 3) can be used. The current value I is, for example, a positive value in a case of charge, and is a negative value in a case of discharge. V_{OCV} can be obtained from an SOC at an estimation time point using, for example, an SOC-OCV table. The SOC may be calculated by a current integration method. The SOC-OCV table may be provided for each temperature, or a common table may be used. As the temperature, a measurement value of the temperature sensor 56 can be used. The polarization voltage V_{RIC1} may be obtained by, for example, a method such as a sequential least squares or Kalman filtering.

A case where conduction with the discharge current I (conduction according to a preannounced conduction pattern) is performed over predetermined time t seconds from an estimation time point is assumed. As illustrated in FIG. 5, voltage V_{bat} of the energy storage apparatus 1 is obtained by summing the cell voltage V_{cell} of each of n of the energy storage cells 3 and voltage caused by a structural resistance component. Using an energy storage apparatus model, the voltage V_{bat} of the energy storage apparatus 1 at a time point after t seconds can be estimated by Formula (2) below using V_{OCV}, I, R₀, R₁, C₁, and R_{struct}.

$$[ Mathematical formula 2 ]$$

$${V}_{bat} = {\sum }_{cell 1}^{cell 4} {V}_{ocv} ( t ) + ( {R}_{struct} + {\sum }_{cell 1}^{cell 4} {R}_{0} ) \times I + {\sum }_{cell 1}^{cell 4} \{ {R}_{1} I \times ( 1 - {exp}^{- \frac{t}{R 1 C 1}} ) + {V}_{R 1 C 1} ( 0 ) \times {exp}^{- \frac{t}{R 1 C 1}} \} \qquad ( 2 )$$

As the predetermined time t, conduction time provided from a host device can be used. V_{OCV}(t) at a time point after t seconds may be obtained in consideration of a change in an SOC.

Further, voltage of each of the energy storage cells 3 at a time point after t seconds is estimated by using an energy storage cell model that simulates behavior of each of the energy storage cells 3. The voltage V_{cell} of each of the energy storage cells 3 at a time point after t seconds can be estimated by Formula (3) below by using V_{OCV}, I, R₀, R₁, and C₁.

$$[ Mathematical formula 3 ]$$

$${V}_{cell} = {V}_{ocv} ( t ) + {R}_{0} I + \{ {R}_{1} I \times ( 1 - {exp}^{- \frac{t}{R 1 C 1}} ) + {V}_{R 1 C 1} ( 0 ) \times {exp}^{- \frac{t}{R 1 C 1}} \} \qquad ( 3 )$$

Hereinafter, a method of determining the “necessary SOC” will be described.

The energy storage apparatus 1 mounted on a mobile object is required to exhibit predetermined power supply capability with respect to an electric load connected to the energy storage apparatus 1 whenever the mobile object is activated (even when discharge is requested). A 12 V battery mounted on a vehicle is required to maintain voltage equal to or higher than a threshold (for example, 9 V) even when discharge current designated by a host device according to power consumption of the in-vehicle electric load 170 is discharged over predetermined time (t seconds).

It is necessary to prevent power supply capability of a battery from falling below a threshold in a process of discharge in order to estimate full charge capacity from an integrated value of charge current until the battery reaches the full charge state by charging the battery to the full charge capacity after the battery is discharged to a low SOC.

The power supply capability of a battery is not always constant, and changes according to an operation status (temperature, current, degree of deterioration of the energy storage cell 3, and the like) of the battery. In view of the above, the “necessary SOC” according to an operation status is determined using the energy storage apparatus model of Formula (2) or the energy storage cell model of Formula (3).

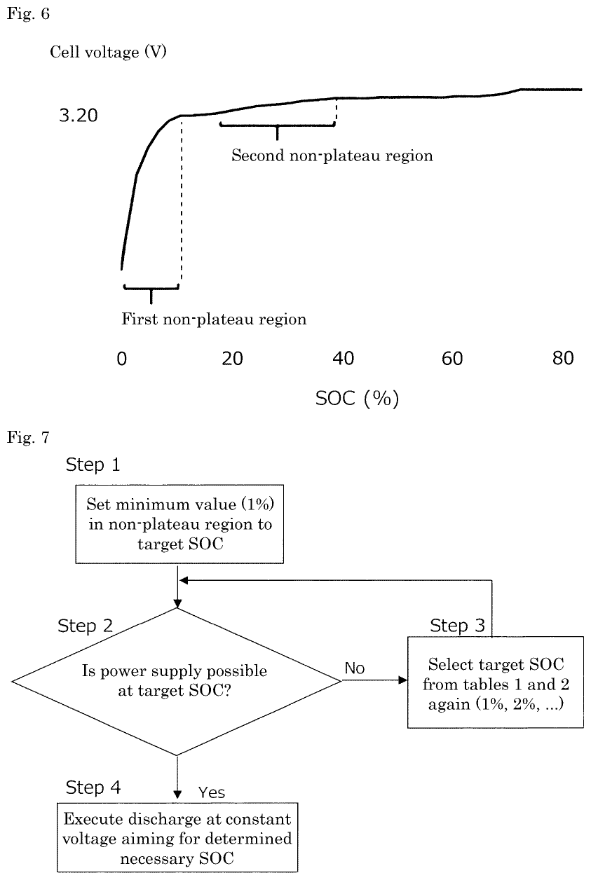

FIG. 6 is a diagram illustrating a part of an SOC-OCV profile in an LFP battery (the energy storage cell 3). The LFP battery includes, in its SOC-OCV profile, a (substantially horizontal) plateau region in which there is almost no voltage change associated with charge and discharge, and a non-plateau region in which there is a voltage change associated with charge and discharge and a slope of a predetermined value or more. In the example of FIG. 6, a first non-plateau region exists over a predetermined range from SOC zero %, and a second non-plateau region exists at a position slightly away from the first non-plateau region. A region between the first non-plateau region and the second non-plateau region and a region exceeding the second non-plateau region are plateau regions in which voltage hardly changes.

In the present embodiment, the necessary SOC is determined so as to be included in the first non-plateau region or the second non-plateau region using Formula (2).

Table 1 shows a relationship between an SOC and OCV in the first non-plateau region and Table 2 shows a relationship between an SOC and OCV in the second non-plateau region in the SOC-OCV profile illustrated in FIG. 6.

TABLE 1

| SOC (%) | OCV (V) | Priority |
|---|---|---|
| 1 | 2.90 | 1 |
| 3 | 3.00 | 2 |
| 5 | 3.05 | 3 |
| 7 | 3.10 | 4 |
| 9 | 3.15 | 5 |

TABLE 2

| SOC (%) | OCV (V) | Priority |
|---|---|---|
| 20 | 3.22 | 6 |
| 25 | 3.24 | 7 |
| 30 | 3.26 | 8 |

A plateau region where OCV is substantially the same (about 3.2 V) is formed between SOC 10% and the SOC 19%.

In the present embodiment, a search for the necessary SOC is started from a lowest SOC value of the energy storage cell 3. FIG. 7 illustrates a simplified flowchart. As a value of V_{OCV}(0) at an estimated time point t=0 of power supply capability, 2.90 V, which is OCV corresponding to SOC 1% in Table 1, is applied to Formula (2) (FIG. 7, Step 1).

OCV, that is, V_{OCV}(t) in a single one of the energy storage cell 3 in Formula (2), which is reached when the discharge current I designated from a host device is discharged over predetermined time (t seconds) is calculated by V_{OCV} (SOC 1%−I×t/full charge capacity×100). Further, a remaining resistance-derived voltage drop in Formula (2) is calculated. In this way, at an estimated time point t=0, reached voltage V_{bat} after conduction of a preannounced conduction pattern is performed to the energy storage apparatus 1 in which an SOC of each of the energy storage cells 3 is 1% is obtained.

When a value of V_{bat} is 9 V or more, it is determined that power supply capability after conduction can be secured (FIG. 7, Step 2: Yes), and SOC 1% is determined as the necessary SOC of each of the energy storage cells 3. When a value of V_{bat} is less than 9 V (FIG. 7, Step 2: No), next, 3.00 V which is OCV corresponding to SOC 3% in Table 1 is applied to Formula (2) (FIG. 7, Step 3), and it is determined whether or not power supply capability can be secured based on obtained reached voltage V_{bat} (FIG. 7, Step 2). This procedure is repeated until an SOC by which power supply capability can be secured is determined.

Aiming at the necessary SOC of each of the energy storage cells 3 determined in this way (aiming at an SOC of the energy storage apparatus 1 at which each of the energy storage cells 3 becomes the necessary SOC), the energy storage apparatus 1 is subjected to CV discharge (FIG. 7, Step 4).

As described above, by determining an SOC value as low as possible as the necessary SOC of each of the energy storage cells 3 while securing power supply capability, OCV reset can be performed when a slope of the SOC-OCV profile is large after depolarization. For this reason, accuracy of estimating full charge capacity or degree of deterioration of the energy storage device can be enhanced.

Conversely, 3.26 V, which is OCV corresponding to a highest SOC value in Table 2 (second non-plateau region), may be applied to Formula (2) as a value of V_{OCV}(0) at an estimated time point t=0 of power supply capability, and a search for the necessary SOC of each of the energy storage cells 3 may be started from the highest SOC value. By the above, the necessary SOC can be determined in short time, and time required for estimation can be shortened.

Further alternatively, the necessary SOC may be searched for from 3.15 V which is OCV corresponding to a highest SOC value in Table 1 (first non-plateau region) toward a low SOC. The necessary SOC may be searched for from 3.22 V which is OCV corresponding to a lowest SOC value in Table 2 (second non-plateau region) toward a high SOC.

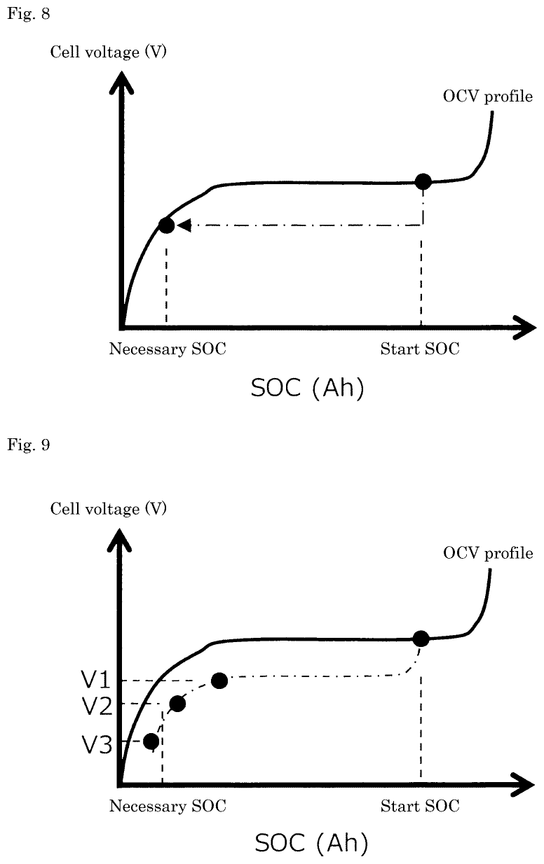

In FIG. 8, voltage behavior of the energy storage cell 3 in a case where CV discharge is performed from a discharge start SOC (SOC at an estimation time point t=0) to the necessary SOC is indicated by an alternate long and short dash line. The CV discharge may be ended at a time point at which discharge current becomes equal to or less than a threshold (for example, 1 A or less). In FIG. 8, an energy storage device is subjected to CV discharge in the entire region in a process of discharge for estimating full charge capacity or degree of deterioration of the energy storage device. Alternatively, the energy storage device may be subjected to CCCV discharge.

An advantage of CV discharge of an energy storage device will be described with reference to a case of CC discharge illustrated in FIG. 9.

In the CC discharge, discharge is stopped based on voltage of the energy storage cell 3 detected by the voltage sensor 55 (see FIG. 3). Cell voltage detected by the voltage sensor 55 reflects internal resistance (polarization). A difference between a solid line (true OCV profile) and an alternate long and short dash line (cell voltage behavior associated with CC discharge) in FIG. 9 indicates polarization. This polarization varies depending on an operation status (temperature, current, degree of deterioration of an energy storage device, and the like) of the energy storage device. For this reason, when CC discharge is performed toward the necessary SOC determined by the above-described method (see FIG. 7), there is a high degree of difficulty in appropriately setting cell voltage for end-of-discharge determination.

The necessary SOC is determined to be included in the non-plateau region in the SOC-OCV profile by the above-described method, but in a case where end-of-discharge cell voltage is set to V1 in FIG. 9, discharge is stopped at a point away from the necessary SOC toward a high SOC. In this case, since each of the energy storage cells 3 included in the energy storage apparatus 1 does not deviate from the plateau region, OCV reset of an SOC cannot be appropriately performed after depolarization. For this reason, even if charging is performed toward full charge, full charge capacity or degree of deterioration of the energy storage device cannot be accurately estimated. The process fails.

In a case where end-of-discharge cell voltage is set to V2 in FIG. 9, discharge is stopped near the necessary SOC that deviates from the plateau region. For this reason, OCV reset of an SOC is performed after depolarization, and charging is performed from there toward full charge, so that full charge capacity or degree of deterioration of the energy storage device can be accurately estimated. The process is successful.

In a case where end-of-discharge cell voltage is set to V3 in FIG. 9, discharge is stopped below the necessary SOC. In this state, although it deviates from the plateau region, predetermined power supply capability cannot be exhibited. The process fails.

It is required to set V2 in FIG. 9, that is, a voltage value corresponding to the necessary SOC as end-of-discharge voltage. However, as described above, polarization varies depending on an operation status of an energy storage device. Therefore, it is difficult to stably perform such setting.

On the other hand, as illustrated in FIG. 8, an energy storage device is subjected to CV discharge toward the necessary SOC, so that the determined necessary SOC can be stably reached. An energy storage device may be subjected to CV discharge at voltage at a point where the determined necessary SOC and an SOC-OCV profile intersect each other. Alternatively, an energy storage device may be subjected to CCCV discharge so that the necessary SOC is reached in short time.

After the necessary SOC is reached by the CV discharge, an energy storage device is left without being charged or discharged, and after depolarization, voltage of the energy storage cell 3 is detected by the voltage sensor 55 to acquire OCV (alternatively, a value that can be regarded as OCV), and OCV reset is performed on the SOC. This process is preferably performed while a mobile object is stopped (for example, during parking of a vehicle). Since the necessary SOC is calculated and secured, an energy storage device can exhibit predetermined power supply capability whenever a mobile object is activated.

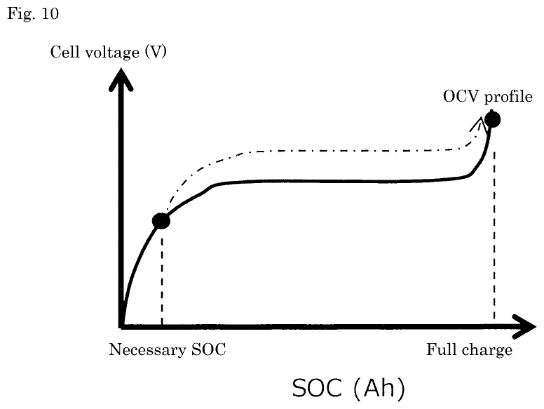

In FIG. 10, voltage behavior of the energy storage cell 3 in a case of charging from the necessary SOC to a full charge state is indicated by an alternate long and short dash line. By adding an integrated value of charge current during charging from the necessary SOC to a full charge state to an OCV-reset SOC, full charge capacity or degree of deterioration of an energy storage device can be accurately estimated.

The present invention is not limited to the above-described embodiment, and can be appropriately changed. The disclosed energy storage apparatus 1, estimation device 2, estimation method, and computer program may be applied to applications other than those for a mobile object. The energy storage apparatus may be a high-voltage battery.

An energy storage device may be first charged to a full charge state, then subjected to CV discharge (alternatively, CCCV discharge) to the necessary SOC, and full charge capacity or degree of deterioration may be estimated based on an integrated value of discharge current.

The estimation device 2 may be provided away from an energy storage device. The estimation method and the computer program may be implemented by a computer (for example, an ECU and a remote monitoring computer) located away from an energy storage device.

Embodiments of the present invention may be implemented as described below.

### First Modification Example

An estimation device including a control unit that estimates full charge capacity or degree of deterioration of an energy storage device, in which
the control unit
estimates full charge capacity or degree of deterioration of the energy storage device based on an integrated value of charge current from a necessary SOC, which is determined to be included in any of a plurality of non-plateau regions in an SOC-OCV profile of the energy storage device, to a full charge state of the energy storage device or an integrated value of discharge current from the full charge state to the necessary SOC, in a case where the energy storage device is discharged until the necessary SOC is reached and the energy storage device is charged to the full charge state.

### Second Modification Example

An estimation device including a control unit that estimates full charge capacity or degree of deterioration of an energy storage device, in which
the control unit
estimates the full charge capacity or the degree of deterioration of the energy storage device based on an integrated value of charge current from a necessary SOC, which is searched for in a predetermined order from an SOC value in a non-plateau region in an SOC-OCV profile of the energy storage device, to a full charge state of the energy storage device or an integrated value of discharge current from the full charge state to the necessary SOC, in a case where the energy storage device is discharged until the necessary SOC is reached and the energy storage device is charged to the full charge state.

### Third Modification Example

An estimation device including a control unit that estimates full charge capacity or degree of deterioration of an energy storage device, in which
the control unit
estimates the full charge capacity or the degree of deterioration of the energy storage device based on an integrated value of charge current from a necessary SOC, which is determined using an energy storage device model that simulates voltage behavior of the energy storage device accompanying discharge, to a full charge state of the energy storage device or an integrated value of discharge current from the full charge state to the necessary SOC, in a case where the energy storage device is discharged until the necessary SOC is reached and the energy storage device is charged to the full charge state.

The energy storage device model may be an energy storage apparatus model that simulates behavior of an energy storage apparatus including a plurality of energy storage cells and a conductive member.

In the estimation device, a resistance component of the conductive member may be given to the energy storage apparatus model.

1. An estimation device comprising a control unit that estimates full charge capacity or degree of deterioration of an energy storage device, wherein
the control unit
estimates the full charge capacity or the degree of deterioration of the energy storage device based on an integrated value of charge current from a necessary state of charge (SOC) to a full charge state of the energy storage device, in a case where the energy storage device is discharged at constant voltage until the necessary SOC is reached and the energy storage device is charged to the full charge state, or an integrated value of discharge current from the full charge state to the necessary SOC.

2. The estimation device according to claim 1, wherein the necessary SOC is determined to be included in a non-plateau region in an SOC-open circuit voltage (OCV) profile of the energy storage device.

3. The estimation device according to claim 1, wherein the necessary SOC is determined using an energy storage device model that simulates voltage behavior of the energy storage device accompanying discharge.

4. The estimation device according to claim 3, wherein the energy storage device model is an energy storage apparatus model that simulates behavior of an energy storage apparatus including a plurality of energy storage cells and a conductive member.

5. The estimation device according to claim 4, wherein a resistance component of the conductive member is given to the energy storage apparatus model.

6. The estimation device according to claim 1, wherein the control unit starts a search for the necessary SOC in a predetermined order from any of a plurality of SOC values included in the non-plateau region.

7. An energy storage apparatus comprising: the estimation device according to claim 1; and a plurality of energy storage cells.

8. An estimation method of estimating full charge capacity or degree of deterioration of an energy storage device, the estimation method comprising:
causing the energy storage device to be discharged at constant voltage until a necessary state of charge (SOC) is reached;
causing the energy storage device to be charged to a full charge state of the energy storage device; and
estimating the full charge capacity or the degree of deterioration of the energy storage device based on an integrated value of charge current from the necessary SOC to the full charge state or an integrated value of discharge current from the full charge state to the necessary SOC.

9. A computer program for causing a computer that estimates full charge capacity or degree of deterioration of an energy storage device to execute processing of
estimating the full charge capacity or the degree of deterioration of the energy storage device based on an integrated value of charge current from a necessary state of charge (SOC) to a full charge state of the energy storage device, in a case where the energy storage device is discharged at constant voltage until the necessary SOC is reached and the energy storage device is charged to the full charge state, or an integrated value of discharge current from the full charge state to the necessary SOC.
